(19) United States
(12) Patent Application Publication
(10) Pub. No.: US 2010/0220443 A1
(43) Pub. Date: Sep. 2, 2010

(54) STRUCTURE IMPROVEMENT FOR A FIXING ELEMENT

(76) Inventor: Li-Hua LI, Hsin Chuan City (TW)

Correspondence Address: SINORICA, LLC, 2275 Research Blvd., Suite 500, ROCKVILLE, MD, 20850, US

(21) Appl. No.: 12/394,143

(22) Filed: Feb. 27, 2009

(51) Int. Cl. H05K 7/00

(52) U.S. Cl. 361/679.58

(57) ABSTRACT

A fixing element, which is a fixing structure for a positioning bracket of an electronic heat sink element, wherein in one end of the fixing element, an outside diameter of a screw body end which is close to a screw head is not disposed with thread, the diameter of the screw body is slightly lesser than an aperture of a joint hole in a bolt hole of a stanchion of a positioning bracket, and the outside diameter thereof is fit in an elastic element; in the other end of the aforementioned fixing element, two different threads are disposed along the axis of the screw body, which is a self tapping thread section and a second thread section respectively, the outside diameter of the self tapping thread section is larger than the aperture of the joint hole in the bolt hole of the stanchion of the positioning bracket, by the tapping effect of the self tapping thread of the fixing element, the fixing element get stuck at the joint hole in the bolt hole of the stanchion of the positioning bracket, then an extraction of the fixing element from the joint hole of the positioning bracket is avoided, a second thread section having a proper length is connected following a back end of the self tapping thread section, the outside diameter of the second thread section is also lesser than the aperture of the joint hole in the bolt hole of the stanchion of the positioning bracket, the second thread section portion is a screw tooth for normal screwing, for locking the electronic heat sink element on a backing of a motherboard.

### BACKGROUND OF THE INVENTION

1. Field of the Invention

The present invention relates to a structure improvement for a fixing element, and more particularly, to a fixing structure for the assembly and position of a positioning bracket of an electronic heat sink element.

2. Description of Related Art

FIG. 1 and 2 show a conventional screw construction used for the locking of a heat sink element of an electronic product, the conventional screw (200) is disposed with a ring groove (210) at a portion without thread rolling, for inserting a C-type snap ring (220) into the ring groove (210), a diameter of the threaded portion is lesser than the diameter of the unthreaded portion, by passing the screw firstly through an elastic element then through a bolt hole (120) of a stanchion (110) of a positioning bracket (100), the heat sink element is locked to a backing of a motherboard. However such screw locking structure needs to dispose the ring groove (210) in the middle of the screw (200) for the closure of a washer, for example the C-type snap ring (220), so as to avoid the outward looseness of the screw from the bolt hole (120) of the stanchion (110), not only a lot of components are needed and the assembling hours are increased, but also vibration noise should be generated because of the friction between the ring groove and the C-type snap ring (220), even worse situations such as braking of the washer could happen. The present invention is an improved structure correspondingly made to improve the disadvantages existed in the conventional art, i.e. the present invention is an improvement to the fixing element structure, wherein by making the outside diameter of the self tapping thread disposed on the fixing element larger than the diameter of the joint hole of the stanchion of the positioning bracket, and by utilizing the way of tapping locking of the self tapping screw, the effect of preventing the looseness of the fixing element is achieved, the present invention can not only avoid the deficit of requiring the washer for conventional screw, but also can lower the cost of material as well as shorten the manufacturing and assembly hours, enhance the production performance of the product line, and avoid the incurrence of situations such as braking and generating noise vibration due to the usage of the washer.

### SUMMARY OF THE INVENTION

Accordingly, the present invention is directed to provide a fixing element structure that is able to fix a heat sink element rapidly, which is a fixing element improvement that passes the fixing element through a joint hole in a bolt hole, which penetrate through up and down, of a stanchion of the positioning bracket, such that to position the heat sink element. The fixing element of the present invention is disposed with two sections of different threads along the axis of a screw body, an outside diameter of a screw body end which is close to a screw head is not disposed with thread, the diameter thereof is slightly lesser than an aperture of a joint hole in a bolt hole of a stanchion of a positioning bracket, and the outside diameter thereof is fit in an elastic element; the other end of the fixing element is disposed with a self tapping thread section, the outside diameter of the self tapping thread section is larger than the aperture of the joint hole in the bolt hole of the stanchion of the positioning bracket, a second screw section having a proper length is connected following a back end of the self tapping thread section, the second thread section is a screw tooth for normal screwing; by using the tapping effect of the self tapping thread, the utility model structure of the present invention passes through the joint hole in the bolt hole of the stanchion of the positioning bracket, such that the fixing element get stuck in the joint hole, and an extraction of the fixing element from the positioning bracket is avoided. Therefore the fixing element structure of the present invention can prevent the extraction of the fixing element without additionally using a closure element such as a washer and the like, so as to achieve an efficacy of lowering the usage cost of the material and shortening the operation hours. In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic assembled view of a structure for conventionally fixing a heat sinker by using a screw,

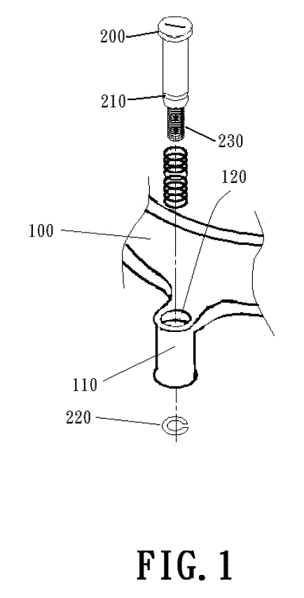

FIG. 2 is a schematic assembled view of a section plane of conventionally fixing the heat sinker by the screw,

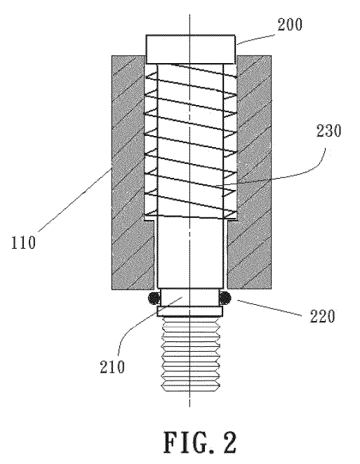

FIG. 3 is a schematic assembled view of a fixing element structure of the present invention, and

FIG. 4 is a schematic assembled view of the section plane structure of the present invention.

### DESCRIPTION OF EMBODIMENTS

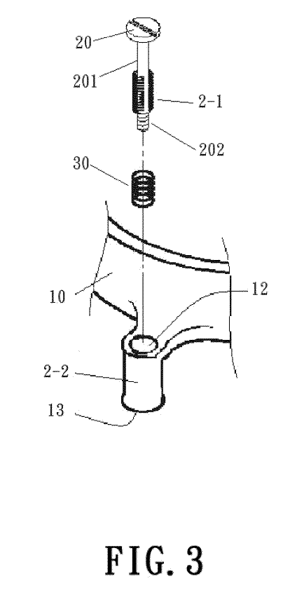

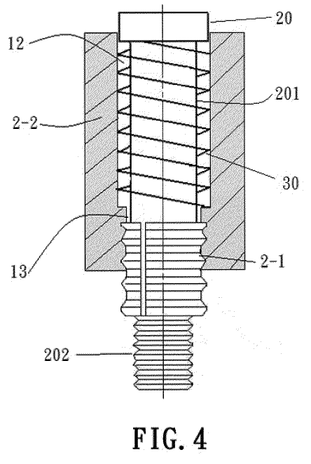

Referring to FIG. 3 and 4, which are drawings of the embodiments wherein the fixing element (20) of the present invention is used to lock the heat sink element, the fixing element (20) of the present invention is disposed with two sections of different threads along the axis of the screw body (201), while the outside diameter of the screw body end which is close to the screw head is not disposed with thread, and the diameter thereof is slightly lesser than the aperture of the joint hole in the bolt hole of the stanchion of the positioning bracket, and the outside diameter thereof is fit in an elastic element (30); the other end of the fixing element (20) is disposed with a self tapping thread section (2-1), wherein the outside diameter of the self tapping thread section (2-1) is larger than the aperture of the joint hole (13) in the bolt hole (12) of the stanchion (2-2) of the positioning bracket (10), and a second thread section (202) having a proper length is connected following the back end of the self tapping thread section (2-1), the diameter of the second thread section (202) is also lesser than the aperture of the joint hole (13) in the bolt hole (12) of the stanchion (2-2) of the positioning bracket (10), the second thread section (14) portion is a screw tooth for normal screwing; by using the tapping effect of the self tapping thread, the utility model structure of the present invention passes through the joint hole in the bolt hole of the stanchion of the positioning bracket, such that the fixing element get stuck in the joint hole, and the extraction of the fixing element from the positioning bracket is avoided. With the utility model screw structure, the fixing element of the present invention uses the structure wherein the outside diameter of the self tapping thread portion is larger than the aperture of the joint hole of the positioning bracket, together with the tapping effect of the self tapping screw tooth, to prevent the fixing element from looseness, the herein disclosed technique content has following advantages comparing to the conventional art:

(1) The present invention can achieve the efficacy and object that the conventional art wants to achieve without using the washer, the assembly operation is simple, the working hours can be decreased, and the working efficiency is increased.

(2) The present invention uses the self tapping screw for position, and locks firmly, such that the extraction of the screw from the positioning bracket can be prevented.

(3) The present invention doesn't use washer, which can lower the material cost, prevent the washer from braking, and prevent the generation of noise vibration.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fixing element structure improvement, which is a fixing structure for a positioning bracket of an electronic heat sink element, wherein in one end of the fixing element, an outside diameter of a screw body end that is close to a screw head is not disposed with a thread, the diameter of the screw body is slightly lesser than an aperture of a joint hole in a bolt hole of a stanchion of a positioning bracket, and the outside diameter thereof is fit in an elastic element, wherein: in the other end of the aforementioned fixing element, two different threads are disposed along an axis of the screw body, which are a self tapping thread section and a second thread section respectively, the outside diameter of the self tapping thread section is larger than the aperture of the joint hole in the bolt hole of the stanchion of the positioning bracket, by a tapping effect of the self tapping thread of the fixing element, the fixing element get stuck at the joint hole in the bolt hole of the stanchion of the positioning bracket, then an extraction of the fixing element from the joint hole of the positioning bracket is avoided, the second thread section having a proper length is connected following a back end of the self tapping thread section, the outside diameter of the second thread section is also lesser than the aperture of the joint hole in the bolt hole of the stanchion of the positioning bracket, the second thread section portion is a screw tooth used for normal screwing, for locking the electronic heat sink element to a backing of a computer motherboard.
